(19) United States
(12) Patent Application Publication
(10) Pub. No.: US 2024/0288703 A1
(43) Pub. Date: Aug. 29, 2024

(54) LIGHT CONTROL LAYER FOR AMBIENT CONTRAST CONTROL

(71) Applicant: 3M INNOVATIVE PROPERTIES COMPANY, St. Paul, MN (US)

(72) Inventors: Nicholas C. Erickson, Saint Paul, MN (US); Raymond J. Kenney, Woodbury, MN (US); Daniel J. Schmidt, Woodbury, MN (US); Brett J. Sitter, Marine on St Croix, MN (US); Kevin W. Gotrik, Hudson, WI (US); Stephen M. Menke, Eagan, MN (US); Jathan D. Edwards, Afton, MN (US)

(21) Appl. No.: 18/688,909

(22) PCT Filed: Sep. 23, 2022
(86) PCT No.: PCT/IB2022/059046

§ 371 Date: Mar. 4, 2024

Related U.S. Application Data
(60) Provisional application No. 63/249,934, filed on Sep. 29, 2021.

(51) Int. Cl. G02B 27/09; G02B 5/30; H10K 59/80

(52) U.S. Cl. CPC G02B 27/0988; G02B 5/3033; G02B 27/0922; H10K 59/8792

(57) ABSTRACT

A light control layer includes alternating transmissive and absorptive regions, along one or two dimensions. The light control layer may be substantially transparent, or have high transmission, for light incident at or near a normal angle to its surface, while absorbing light incident at angles away from normal. The height of the absorptive region, defined orthogonal to the local display surface, may be much greater than the width of the absorptive region resulting in a high aspect ratio structure. The width of the absorptive region may be relatively thin compared to the width of a pixel in a display. The light control layer may be applied to a display or incorporated into a display. The light control layer may be part of a film stack including other functional layers that cooperatively provide desirable optical properties.

The present disclosure generally relates to displays and particularly to light control layers for displays that provide ambient contrast control.

Some displays, such as organic light-emitting diode (OLED) displays, are known to have poor angular color uniformity. Existing color correction components have been demonstrated to improve such uniformity but result in the display exhibiting significantly higher ambient reflectance and lower ambient contrast under bright conditions, such as direct sunlight, than OLED displays without a color correction components.

### SUMMARY

The techniques of this disclosure generally relate to using alternating absorbing and transmissive structures to reduce reflections of ambient light from a display, which may result in improved control of ambient reflectance to a viewer of the display, compared to displays used without a light control layer. A light control layer includes alternating transmissive and absorptive regions, along one or two dimensions. The light control layer may be substantially transparent, or have high transmission, for light incident at or near a normal angle to its surface, while absorbing light incident at angles away from normal. This light control layer may be used to reduce ambient reflectance and improve the ambient contrast ratio (ACR) of a display. The height of the absorptive region, defined orthogonal to the local display surface, may be much greater than the width of the absorptive region resulting in a high aspect ratio structure. The width of the absorptive region may be relatively thin compared to the width of a pixel in a display. The light control layer may be applied to a display or incorporated into a display. The light control layer may be part of a film stack including other functional layers that cooperatively provide desirable optical properties.

In one aspect, a light control film includes a light control layer. The light control layer includes a first major surface and a second major surface opposite the first major surface. Each surface extends in at least a first direction and a second direction. The surfaces are separated along a third direction orthogonal to the first and second directions. The light control layer also includes at least one transmissive structure defining transmissive regions disposed between the first major surface and the second major surface. Further, the light control layer includes at least one absorptive structure defining absorptive regions disposed between the first major surface and the second major surface. A first cross-section of the film extending along the first and third directions has alternating transmissive and absorptive regions along the first direction. A second cross-section of the film extending along the second and third directions has at least one transmissive region or absorptive region along the second direction. The transmissive regions have an average maximum height H1 defined along the third direction and average median width W1 defined along the first direction. The absorptive regions have an average maximum height H2 defined along the third direction and average median width W2 defined along the first direction. H2/W1 is greater than or equal to 1:1. H2/W2 is greater than or equal to 20:1.

In another aspect, an optical film is configured to be disposed on, and improve an ambient contrast ratio of, a display. The optical film includes a plurality of alternating visible light transmissive and visible light absorbing regions disposed and extending between opposing major first and second surfaces. The light absorbing regions have an average median width W2 and an average maximum height H2 such that H2/W2≥10:1 and, for substantially Lambertian incident light in a visible wavelength range from about 380 nm to about 780 nm, an optical transmittance of the optical film versus an incident angle of the incident light has a full width at half maximum (FWHM) of greater than or equal to about 80 degrees.

In yet another aspect, an optical film is configured to be disposed on, and improve an ambient contrast ratio of, a display. The optical film includes a plurality of alternating visible light transmissive and visible light absorbing regions disposed and extending between opposing major first and second surfaces. The light absorbing regions have an average median width W2 and an average maximum height H2 such that H2/W2≥10:1 and an average pitch distance P2 between adjacent visible light absorbing regions such that P2/H2>1.

### BRIEF DESCRIPTION OF DRAWINGS

FIG. 1 illustrates a perspective view of a display including a light control layer.

FIG. 2A illustrates a first cross-sectional view of the light control layer of FIG. 1.

FIG. 2B illustrates a second cross-sectional view of the light control layer of FIG. 1.

FIG. 2C illustrates a third cross-sectional view of the light control layer of FIG. 1.

FIG. 2D illustrates a top-down view of the display of FIG. 1.

FIG. 3 illustrates a cross-sectional view of another embodiment of a display including the light control layer of FIG. 1 and other functional optical layers.

FIG. 4 illustrates a cross-sectional view of yet another embodiment of a display.

FIG. 5 illustrates an enlarged cross-sectional view of an alternative embodiment of a light control layer structures that may be used in the displays of FIGS. 1, 3, and 4 and various parameters that may be used to describe the light control layer structures.

FIGS. 6-7 illustrate cross-sectional views of alternative embodiments of light control layers that may be used in the displays of FIGS. 1, 3, and 4.

FIG. 8 illustrates an angular transmission profile of a light control film.

### DETAILED DESCRIPTION

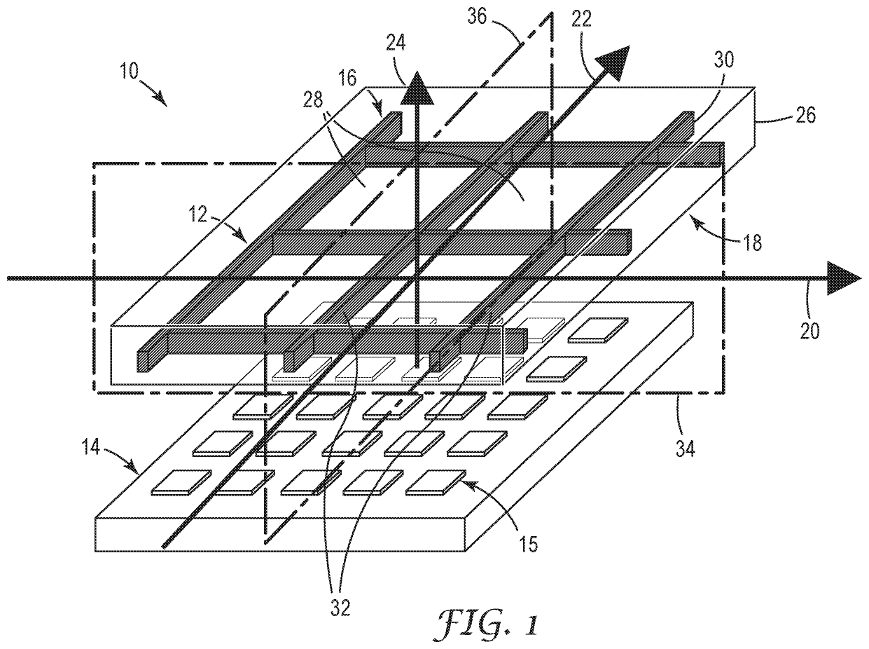

FIG. 1 shows a display 10 including a light control layer 12 and a light-emitting layer 14. The display 10 may be an electronically controlled display, which may be capable of producing an image, such as an OLED display usable in electronic devices, such as cell phones, tablets, and televisions. The display 10 may be connected to, or include, suitable connections and control electronics to operate. When used in high ambient brightness conditions, the ACR of OLED displays may be detrimentally impacted by reflections from layers or optical structures within the displays. Optical enhancement films for OLED displays, such as color correction components for improving angular color uniformity, tend to have the drawback of increasing the reflectance of ambient light, especially diffuse reflectance. Diffuse reflectance refers to light reflected from a display from a non-specular direction over one or more angular ranges. Diffuse reflectance may be measured according to ASTM E1164.

The light control layer 12 includes alternating absorbing and transmissive structures to reduce reflections of ambient light from the display 10, which may result in improved control of ambient contrast to a viewer of the display 10, compared to displays used without a light control layer. In particular, the light control layer 12 may improve the ACR, reduce diffuse reflectance, or both for displays impacted by the inclusion of color correction components.

The alternating pattern of transmissive and absorptive regions of the light control layer 12 may extend along one, two, or more directions. The absorptive structure 30 may also be described as a louver having slats or strips (absorptive regions) at regular or irregular intervals to allow light to pass through between the slats or strips (transmissive regions). In general, the alternating pattern may be defined along at least one dimension (1D). In some embodiments, the alternating pattern may be defined in only one dimension. In other embodiments, an alternating pattern may be defined along two dimensions (2D). In the illustrated embodiment, the light control layer 12 has a 2D alternating pattern. The light control layer 12 is substantially transparent to light incident near normal but capable of absorbing light at high angles away from normal. The light control layer 12 may also be described as a high angle light absorbing (HALA) layer.

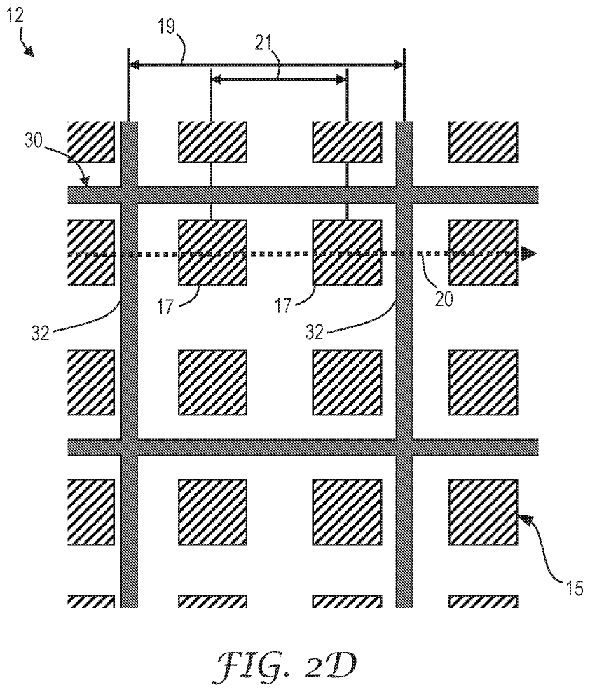

The light control layer 12 may be applied to a display or incorporated into a display, such as the illustrated display 10. The light control layer 12 may be part of a light control film or optical film, such as light control film 51 (FIG. 3), which may include other functional layers, such as a color correction component, in a film stack that together cooperatively provide desirable optical properties to the display 10.

In general, light control layers or light control films, of the present disclosure provide a high axial transmission and a relatively high full width at half maximum (FWHM) value. The axial transmission may be greater than or equal to 75%, 80%, 85%, 90%, or even 95% as measured with a hazemeter (e.g., BYK Instruments USA (Columbia, MD) haze-gard i) according to ASTM D1003: Standard Test Method for Haze and Luminous Transmittance of Transparent Plastics Angular transmission of light through a light control film can be measured with a conoscope, for example, an Eldim EZContrast L80 conoscope (Eldim S. A., Heroville-Saint-Clair, France). Relative transmission (e.g., brightness of visible light) is defined as the percentage of luminance, at a specified viewing angle or range of viewing angles, between a reading with the light control film including the alternating transmissive and absorptive regions and optionally other layers and a reading without the light control film (i.e., the baseline). The viewing angle can range from −90 degrees to +90 degrees. A viewing angle of 0 degrees is orthogonal to light input surface, whereas viewing angles of −90 degrees and +90 degrees are parallel to light input surface. Unless specified otherwise, the relative transmission refers to the relative transmission of visible light having a 380-780 nm wavelength range. For light control films of the present disclosure, FWHM is defined from a cross-section of the conoscopic data. Specifically, FWHM, which has units of degrees, is the width of the relative transmission curve at a relative transmission value corresponding to half of the peak in relative transmission. The nature of the light source can affect the shape (e.g. breadth) of the relative transmission curve. In the present disclose, we define the light source for FWHM measurement as a Lambertian light source as described on page 22 of International Patent Publication No. WO 2019/118685 (Schmidt et al.).

The light-emitting layer 14 may be any suitable substrate capable of mechanically supporting and electrically powering an array of light sources 15. As illustrated, the light-emitting layer 14 includes an array of light sources 15, such as OLEDs arranged in a 2D array to provide a 2D image. The array of light sources 15 may be arranged to form an array of pixels. For example, a pixel in an OLED display may be defined as a cluster of subpixels 17, or different color light sources, such as a red OLED subpixel, a green OLED subpixel, and a blue OLED subpixel. The array of light sources 15 may be at least partially disposed in the light-emitting layer 14. The array of light sources 15 may be disposed on a major surface of the light-emitting layer 14.

In the illustrated embodiment, the light control layer 12 may be disposed on the light-emitting layer 14. As used herein, the term “disposed on” refers to one object being placed on, applied to, coupled to, another object in any suitable orientation. For example, a first object disposed on a second object may be placed on top of, below, or next to, the second object. Disposed may refer to being directly or indirectly disposed.

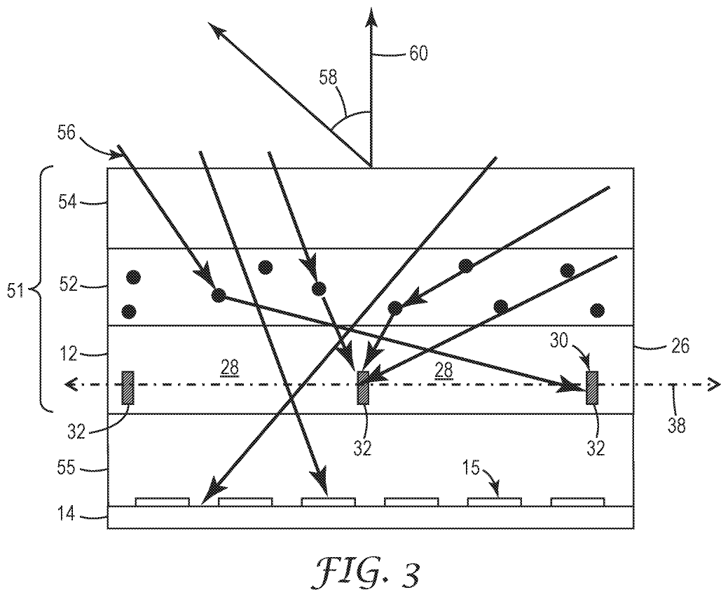

In other embodiments, the array of light sources 15 may be at least partially disposed in a light control layer. The light-emitting layer 14 and the light control layer 12 may be integrally formed into one layer. As can be seen in FIG. 4, the display 100 includes a light control layer 102 having the absorptive structure 30 and an array of light sources 15 in a single layer. The integrated structure shown in FIG. 4 may be manufactured, for example, using lithographic patterning techniques common in OLED manufacturing.

In some embodiments (not shown), the absorptive structure 30 may be co-planar with the array of light sources 15. The absorptive structure 30 may extend on one end from a same plane as the array of light sources 15 instead of, as shown in FIG. 4, a gap being positioned between the plane of the array of light sources 15 and the absorptive structure 30.

In general, the light control layer 12 may be described as having a first major surface 16 and a second major surface 18 opposite the first major surface. Each major surface extends in at least a first direction 20 and a second direction 22. The major surfaces are separated along a third direction 24 orthogonal to the first and second directions.

As illustrated, the light control layer 12 and the light-emitting layer 14 are shown having a substantially planar construction. In other embodiments, the display 10 and the light control layer 12 may be non-planar or flexible. The directions identified are relative to a local region of a non-planar display or relative to a flexible display in a planar position.

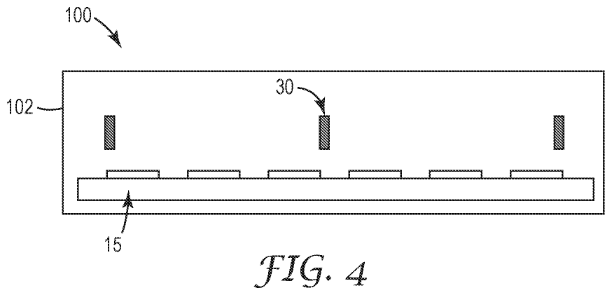

The light control layer 12 includes at least one transmissive structure 26. The transmissive structure 26 is formed of light transmissive material having an absorption coefficient of less than or equal to 0.01 in a wavelength range from 380 nanometers (nm) to 780 nm. The one or more transmissive structures 26 define at least one transmissive region 28 disposed between the first major surface 16 and the second major surface 18 of the light control layer 12. Perhaps as best shown in FIG. 5, one or more transmissive structures 26 may be used to fill, or backfill, to provide a more uniform thickness of the light control layer 12.

The transmissive structure 16 may include a polymerized resin. The polymerizable resin may include a combination of a first and second polymerizable component selected from (meth)acrylate monomers, (meth)acrylate oligomers, and mixtures thereof. As used herein, “monomer” or “oligomer” is any substance that can be converted into a polymer. The term “(meth)acrylate” refers to both acrylate and methacrylate compounds. In some cases, the polymerizable composition may include one or more of a (meth)acrylated urethane oligomer, (meth)acrylated epoxy oligomer, (meth)acrylated polyester oligomer, a (meth)acrylated phenolic oligomer, a (meth)acrylated acrylic oligomer, and mixtures thereof.

The polymerizable resin may be a radiation curable polymeric resin, such as a UV curable resin. In some cases, polymerizable resin compositions useful for the LCF of the present invention may include polymerizable resin compositions, such as those described in U.S. Pat. No. 8,012,567 (Gaides et al.), to the extent that those compositions satisfy the index and absorption characteristics described.

The transmissive structure may include resins suitable for melt extrusion; such resins are transparent materials that are dimensionally stable, durable, weatherable, and readily formable into the desired configuration. Examples of suitable materials include acrylics, which have an index of refraction of about 1.5, such as Plexiglas brand resin manufactured by Rohm and Haas Company (Philadelphia, PA); polycarbonates, which have an index of refraction of about 1.59; reactive materials such as thermoset acrylates and epoxy acrylates; polyethylene based ionomers, such as those marketed under the brand name of SURLYN by Dow Chemical Company (Midland, MI); (poly)ethylene-co-acrylic acid; polyesters; polyurethanes; and cellulose acetate butyrates. Polycarbonates are particularly suitable because of their toughness and relatively higher refractive index. Thermoplastic polyolefins are also particularly suitable; for example, polymethylpentene marketed under the brand name of TPX by Mitsui Chemicals America, Inc. (Rye Brook, NY).

The light control layer 12 also includes at least one absorptive structure 30. The absorptive structure 30 is formed of at least one light absorbing material having an optical density (OD) greater than or equal to 0.5, 1, 1.5, 2, 2.5, or even 3 in a wavelength range from 380 nm to 780 nm. The thickness of the absorptive structure may be at least 50, 100, 150, 200, 250, 300, 350, 400, 450, 500, or even 5000 nanometers. The absorptive structure 30 may include a layer with an extinction coefficient of greater than 0.15, 0.20, 0.25, 0.30, 0.35, or 0.40 at a wavelength in the range of 380 nm to 780 nm. In some embodiments, the absorptive structure 30 includes a core having a first extinction coefficient k1 positioned between two cladding layers having a second extinction coefficient, k2, wherein k2<k1, as described in International Patent Publication No. WO 2020/026139 (Schmidt et al.). The one or more absorptive structures 30 define at least one absorptive region 32 disposed between the first major surface 16 and the second major surface 18.

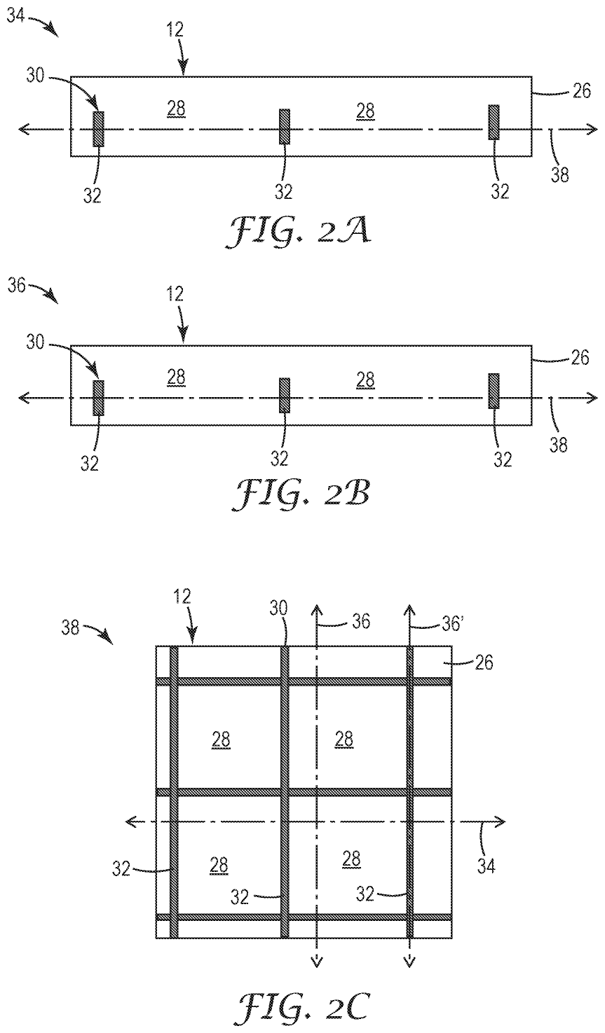

A first cross-section 34 of the light control layer 12, or light control film, is defined extending along the first and third directions 20, 24. FIG. 2A shows a view of the light control layer 12 along the first cross-section 34. The light control layer 12 has alternating transmissive and absorptive regions 28, 32 in the first cross-section 34 along the first direction 20.

A second cross-section 36 of the light control layer 12, or light control film, is defined extending along the second and third directions 22, 24. FIG. 2B shows a view of the light control layer 12 along the second cross-section 34. The light control layer 12 has at least one transmissive region 28 or absorptive region 32 along the second direction 22. In the illustrated embodiment, the second cross-section 36 has alternating transmissive and absorptive regions 28, 32 along the second direction 22. One of ordinary skill in the art will appreciate that depending on where the second cross-section 36 is evaluated, it may be possible for the cross-sectional view of a 2D absorptive structure 30 to have only an absorptive region 32 shown along the second direction 22. For example, if the second cross-section 36′ (FIG. 2C) is used, only absorptive regions 32 will be visible along that cross section.

The absorptive structure 30 of the light control layer 12 may be described as having a 1D or 2D pattern. In the illustrated embodiment, the light control layer 12, or light control film, has a 2D pattern extending along the first and second directions 20, 22 (FIG. 1).

FIG. 2C shows a view of the light control layer 12 along a third cross-section 38, taken along line 38 in FIGS. 2A and 2B. FIG. 2D shows a top-down view of the 2D absorptive structure 30.

The absorptive structure 30 has a 2D pattern or shape, which may be described as a 2D absorptive structure when viewed in the third cross-section 38. In particular, the absorptive structure 30 may be described as having a sparse, 2D absorptive structure 30 in a “grid”-like pattern. The absorptive structure 30 may be described as sparse, for example, when the pitch of the absorptive structure 30 is greater than the pitch of the array of light sources 15.

As used herein, a “pitch” refers to a center-to-center distance between two adjacent similar structures in a particular view and may be defined along any suitable direction, such as the first direction 20 or the second direction 22. A subpixel pitch 21 may be defined as the center-to-center distance between adjacent subpixels 17 when viewed in a top-down view as shown in FIG. 2D. As illustrated, the subpixel pitch 21 is defined along the first direction 20. An absorptive region pitch 19, or louvre pitch, may be defined as the center-to-center distance between adjacent absorptive regions 32 when viewed in a top-down as shown in FIG. 2D. As illustrated, the absorptive region pitch 19 may be defined along the first direction 20.

When describing the light control layer 12, an average pitch may be defined for one or more components. An average subpixel pitch P3 may be defined as an average of the subpixel pitches 21 for a plurality of subpixels 17 in the first or second direction 20, 22. An average absorptive region pitch P2 may be defined as an average of the absorptive region pitches 19 for a plurality of absorptive regions 32 in the same direction. P2/P3 may be greater than or equal to 1:1, 2:1, 3:1, or even 4:1. P2/P3 may be less than or equal to 5:1, 4:1, 3:1, or even 2:1. In some embodiments, P2/P3 may be equal, or 1:1, wherein the absorptive regions 32 are registered, or aligned to, the subpixels 17 such that the absorptive regions 32 are between adjacent subpixels 17.

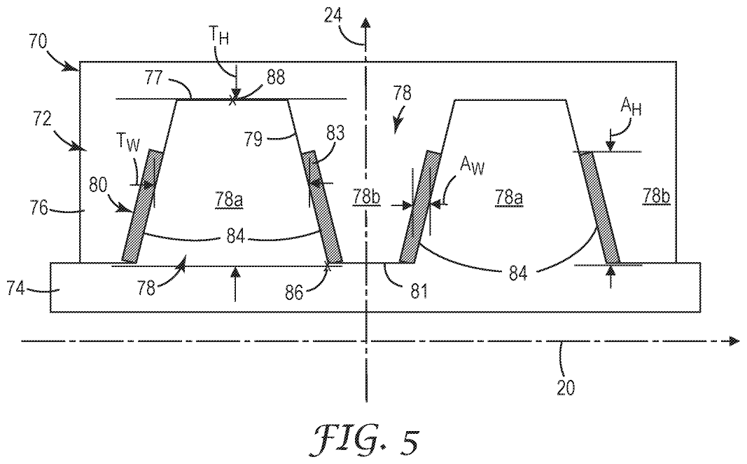

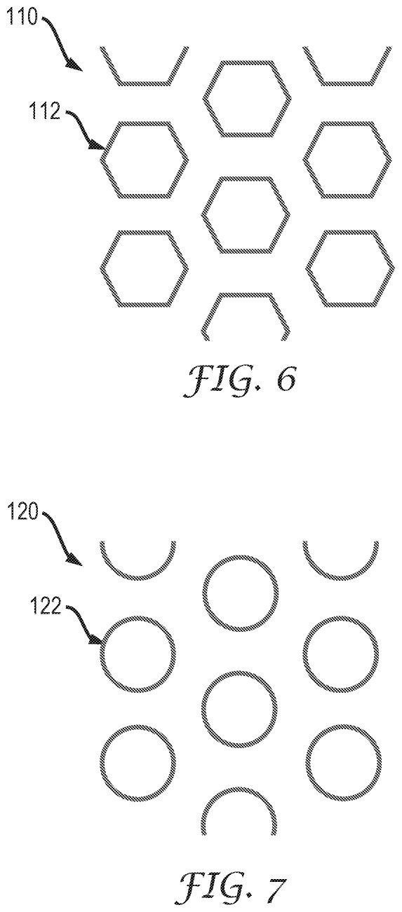

Although a rectangular-grid, or square-grid, pattern is shown, a 2D absorptive structure 30 may have any suitable pattern. The pitch between the absorptive regions 32 may be regular or irregular depending on the pattern of the absorptive structure 30. Other examples of 2D patterns for the absorptive structure 30 include, but are not limited to, a hexagonal grid (see FIG. 6), a circular grid (see FIG. 7), any other suitable polygonal grid, or a curvilinear grid (or grid having curved lines instead of straight lines). P2 may be defined for any of these patterns.

FIG. 6 shows a light control layer 110 along a third cross-sectional plane similar to the third cross-sectional plane 38 (FIGS. 2A-2C). The light control layer 110 includes a plurality of hexagonal-shaped absorptive regions 112.

FIG. 7 shows a light control layer 120 along a third cross-sectional plane similar to the third cross-sectional plane 38 (FIGS. 2A-2C). The light control layer 120 includes a plurality of circular-shaped absorptive regions 122.

In other embodiments (not shown), in which a 1D absorptive structure 30 is used, the second cross-section 36 may have only a transmissive region 28 or an absorptive region 32. Suitable patterns for a 1D absorptive structure 30 may be, for example, based on the cross-section of any of the 2D patterns described.

In general, the appropriate pattern may be selected based on reducing ambient reflectance caused by the particular structures of the display 10. The 1D or 2D pattern may also be selected to avoid visual interference effects, such as those caused by Moiré patterns.

FIG. 3 shows a first cross-sectional view of a display 50 similar to the first cross-sectional plane 34 (FIGS. 1 to 2C). The display 50 includes the light control layer 12, the light-emitting layer 14, a refracting or diffracting layer 52, and a circular polarizer layer 54. Many of the components of the display 50 are the same or similar to the components of the display 10 depicted in FIG. 1 except that the display 50 includes a refracting or diffracting layer 52 disposed on the light control layer 12 and a circular polarizer layer 54 disposed on the refracting or diffracting layer 52. The light control layer 12, the refracting or diffracting layer 52, and the circular polarizer layer 54 may be described together as a light control film 51.

In some embodiments, a space or distance may be maintained between the light control layer 12 and the light-emitting layer 14 using an optically clear adhesive layer 55. The optically clear adhesive layer 55 may bond the light control layer 12 to the light-emitting layer 14. The thickness, or height, of the optically clear adhesive layer 55 may be modified to establish a desired distance between the absorptive regions 32 and the array of light sources 15. Alternatively, or in addition to, the optically clear adhesive layer 55, the desired distance may also be maintained by the positioning of the absorptive regions 32 within the transmissive structure 26, as well as the overall thickness, or height, of the transmissive structure 26 of the light control layer 12.

An angle 58 of incident light may be defined relative to a normal 60 orthogonal to a major surface of the light control film 51. In general, the light control film 51 transmits ambient light 56 near normal 60 and absorbs ambient light 56 at higher angles of incidence. In some embodiments, the optical transmittance of the light control layer 12, or the light control film 51, versus the angle 58 of incident ambient light 56 may have a FWHM of greater than or equal to about 80 degrees for substantially Lambertian incident light in a visible wavelength range from about 380 nm to about 780 nm.

Ambient light 56 may first pass through the circular polarizer layer 54 and may be converted to linearly polarized light, then circularly polarized light, before reaching the refracting or diffracting layer 52. The circular polarizer layer 54 may convert circularly polarized light reflected off structures in the display 50 to linearly polarized light before it reenters the ambient environment Some light passing through may be absorbed by the circular polarizer layer 54.

The refracting or diffracting layer 52 may improve angular color uniformity for light emitted from the array of light sources to a viewer or provide other optical functionality, such as brightness enhancement. In general, the refracting or diffracting layer 52 may increase reflections of ambient light 56 from the display 50. The refracting or diffracting layer 52 may increase the angle of some of the ambient light 56 passing through, which may reflect off structures in the display 50 back into the ambient environment, which may be perceived as a “halo” effect to a viewer caused by scattering or haze of ambient light 56, especially in the absence of the light control layer 12.

The absorptive structure 30 of the light control layer 12 has a higher probability to absorb the ambient light 56 at higher incidence angles before or after being refracted or diffracted by structures of the display 50 but before such light goes back into the ambient environment to reduce the “halo” effect. Further, ambient light 56 scattered into totally-internally-reflected (TIR) modes have an even higher probability of being absorbed by the absorptive structure 30, for example, when refractive indices of the refracting or diffracting layer 52 and the light control layer 12 are appropriately selected.

The light control layer 12 may be made in any suitable manner. In some embodiments, a transmissive material forming a transmissive structure 26 may be provided having a plurality of protrusions such that channels are defined between the protrusions. The transmissive structure 26 may then be coated with a light absorbing material forming the absorptive structure 30 cover at least the sidewall surfaces of the transmissive structure protrusions. If needed, light absorbing material on the top surfaces of the transmissive structure protrusions may be etched away. The remaining space of the channels between the coated sidewall surfaces of the protrusions may be backfilled with the same transmissive material or an index-matching transmissive material. The transmissive regions 28 may be defined in the transmissive structure 26 between each coated sidewall surface. In some embodiments, the transmissive regions 28 may be defined to include the transmissive material forming the protrusions and the backfilled transmissive material in the channels. The absorptive regions 32 include the coated sidewall surfaces. Examples of suitable techniques to make the light control layer 12 may be found, for example, in International Publication No. WO 2020/250090 A1 (Schmidt et al.), which is incorporated herein by reference, and describes a “layer-by-layer self-assembly process.” Such a layer-by-layer technique may be used to provide extremely thin, highly absorbing coatings can be formed on the vertical facets of a microreplicated surface of a transmissive material to provide ultra-thin absorbing “louver” light control layers.

In some embodiments, the absorptive structure 30 may be formed within a single layer. In other embodiments, the absorptive structure 30 may be formed in two or more layers, or sublayers, in the light control layer 12. A first layer of the absorptive structure 30 may be formed and filled in, and a second, additional layer of the absorptive structure 30 may be formed in filled in on the first layer. In some embodiments, a first layer of the absorptive structure 30 may be formed as parallel lines in a first direction, and a second layer of the absorptive structure 30 may be formed as parallel lines in a second direction different than the first direction, such as perpendicular, to form a rectangular grid pattern similar to the rectangular grid pattern shown in FIGS. 1 to 2D.

The absorptive structures 30 may be formed of any suitable absorptive material, such as those found in International Publication No. WO 2020/250090 A1 (Schmidt et al.). Light absorbing materials useful for forming the absorptive structure 30 having light absorptive regions 32 can be any suitable material that functions to absorb or block light at least in a portion of the visible spectrum defined as 380 to 780 nm. In typical embodiments, the light absorbing materials also absorb or block at least a portion of the ultraviolet (UV) and/or infrared (IR) spectrum. Preferably, the light absorbing material can be coated or otherwise provided on the side walls of the light transmissive regions 28 to form absorptive regions 32 in the light control layer 12. Exemplary light absorbing materials include a black or other light absorbing colorant (such as carbon black or another pigment or dye, or combinations thereof). Other light absorbing materials can include particles or other scattering elements that can function to block light from being transmitted through the light absorbing regions.

In some embodiments, the absorptive regions 32 of the absorptive structures 30 include light-absorbing or light-reflecting particles and optionally a polymer binder. In some embodiments, the light-absorbing or light-reflecting particles and the polymer binder have complementary functional groups, for example, positively and negatively charged functional groups, or hydrogen bond donors and acceptors. In some embodiments, the polymer binder is a dried aqueous dispersion of an organic polymer.

Suitable polymers that include a plurality of positively charged ionic (or ionizable) groups (i.e., polycationic polymers) can be derived from various monomers.

Suitable monomers may include primary amino-containing monomers and their salts (e.g., hydrochloride salts), such as vinyl amine, allyl amine, aminoalkyl (meth)acrylamide, aminoalkyl (meth)acrylate, and 2-N-morpholinoalkyl (meth)acrylate.

Suitable monomers may include secondary amino-containing monomers and their salts (e.g., hydrochloride salts), such as alkylaminoalkylene (meth)acrylates (for example, 2-(methylamino)ethyl (meth)acylate). Suitable monomers may include tertiary amino-containing monomers and their salts (e.g., hydrochloride salts), such as various N,N-dialkylaminoalkyl (meth)acrylates and N,N-dialkylaminoalkyl (meth)acrylamides. Non-limiting examples of these include N,N-dimethyl aminoethyl (meth)acrylate), N,N-dimethylaminoethyl (meth)acrylamide, N,N-dimethylaminopropyl (meth)acrylate, N,N-dimethylaminopropyl (meth)acrylamide, N,N-diethylaminoethyl (meth)acrylate, N,N-diethylaminoethyl (meth)acrylamide, N,N-diethylaminopropyl (meth)acrylate, N,N-diethylaminopropyl (meth)acrylamide, (tert-butylamino)alkyl methacrylate, and (tert-butylamino)alkyl methacrylamide. Suitable monomers may include quaternary amino-containing monomers, such as methacryloylaminopropyl trimethylammonium chloride, diallyldimethylammonium chloride, and 2-acryloxyalkyltrimethylammonium chloride

Some of the polycationic polymers used for layer-by-layer coating include linear and branched poly(ethylenimine) (PEI), poly(allylamine hydrochloride), polyvinylamine, chitosan, polyaniline, polyamidoamine, poly(vinylbenzyltrimethylamine), polydiallyldimethylammonium chloride (PDAC), poly(dimethylaminoethyl methacrylate), poly[(3-methacryloylamino)propyl]-trimethylammonium chloride, and combinations thereof, including copolymers thereof.

Suitable polycations may also include polymer latexes, dispersions, or emulsions with positively charged functional groups on the surface. Examples include SANCURE 20051 and SANCURE 20072 cationic polyurethane dispersions available from Lubrizol Corporation (Wickliffe, OH). Suitable polycations may also include inorganic nanoparticles (for example, aluminum oxide, zirconium oxide, titanium dioxide) suitably below their native isoelectric point, or alternatively surface-modified with positively charged functional groups.

Suitable polymers that include negatively charged ionic (or ionizable) groups (i.e., polyanionic polymers) can be derived from various monomers, such as acid monomers, and salts thereof. Suitable monomers may include, such as (meth)acrylic acid, β-carboxyethyl (meth)acylate, 2-(meth)acryloyloxyethyl phthalic acid, 2-(meth)acryloyloxy succinic acid, vinyl phosphonic acid, vinyl sulfonic acid, styrene sulfonic acid, 2-acrylamido-2-methylpropane sulfonic acid, (meth)acrylate salts (i.e., zinc acrylate, zirconium acrylate, etc.), carboxyethyl (meth)acrylate salts (i.e., zirconium carboxyethyl acrylate), 2-sulfoalkyl (meth)acrylate, phosphonoalkyl (meth)acrylate, and phosphoric acid 2-hydroxyethyl methacrylate ester.

Some of the polyanionic polymers used for layer-by-layer coating include poly(vinyl sulfate), poly(vinyl sulfonate), poly(acrylic acid) (PAA), poly(methacrylic acid), poly(styrene sulfonate), dextran sulfate, heparin, hyaluronic acid, carrageenan, carboxymethylcellulose, alginate, sulfonated tetrafluoroethylene based fluoropolymers such as NAFION, poly(vinylphosphoric acid), poly(vinylphosphonic acid), and combinations thereof, including copolymers thereof.

Suitable polyanions may also include polymer latexes, dispersions, or emulsions with negatively charged functional groups on the surface. Such polymers are available, for example, under the JONCRYL tradename (BASF, Florham Park, NJ), CARBOSET tradename (Lubrizol Corporation), and NEOCRYL tradename (DSM Coating Resins, Wilmington, MA). Suitable anions may also include inorganic nanoparticles (for example, silicon oxide, aluminum oxide, zirconium oxide, titanium dioxide, nano-clay) suitably above their native isoelectric point, or alternatively surface-modified with negatively charged functional groups.

When the light absorbing material (e.g., coating) for the absorptive structure 30 includes particles, the particles have a median particle size (D50) equal to or less than the thickness of the light absorbing material (e.g., coating) or in other words substantially less than the width of the absorptive regions W_{A}.

The median particle size is generally less than 1 micrometer. In some embodiments, the median particle size is less than or equal to 900, 800, 700, 600, or 500 nm. In some embodiments, the median particle size is less than or equal to 450, 400, 350, 300, 250, 200, or 100 nm. In some embodiments, the median particle size is less than or equal to 90, 85, 80, 75, 70, 65, 60, 55, or 50 nm. In some embodiments, the median particle size is less than or equal to 30, 25, 20, or 15 nm. The median particle size is typically greater than or equal to 1, 2, 3, 4, or 5 nm. The particle size of the nanoparticles of the absorptive regions 32 can be measured using transmission electron microscopy (TEM) or scanning electron microscopy (SEM), for example.

Suitable light absorbing colorants, such as pigments or dyes, for the absorptive structure 30 are available commercially as colloidally stable water dispersions from commercially available sources. Particularly suitable pigments include those available from Cabot Corporation, Alpharetta, Georgia, under the CAB-O-JET trade name, such as 200 (black), 300 (black), 352K (black), 400 (black), 250C (cyan), 260M (magenta), and 270Y (yellow). Other particularly suitable pigments include those available from Orient Corporation, Cranford, New Jersey, under the BONJET Black Series trade name, such as CW-1, CW-2, and CW-3. The light absorbing (e.g., pigment) particles are typically surface treated to impart ionizable functionality. Examples of suitable ionizable functionality for light absorbing (e.g., pigment) particles include sulfonate functionality, carboxylate functionality as well as phosphate or bisphosphonate functionality. In some embodiments, surface treated light absorbing (e.g., pigment) particles having ionizable functionality are commercially available. For example, CAB-O-JET pigments sold under the trade names 250C (cyan), 260M (magenta), 270Y (yellow), and 200 (black), have sulfonate functionality. As yet another example, CAB-O-JET pigments sold under the trade names 352K (black) and 300 (black) have carboxylate functionality.

When the light absorbing (e.g., pigment) particles for the absorptive structure 30, are not pre-treated, the light absorbing (e.g. pigment) particles can be surface treated to impart ionizable functionality as known in the art.

Metal oxide pigments may be used for the absorptive structure 30, such as metal chromates, molybdates, titanates, tungstates, aluminates, and ferrites. Many contain transition metals like iron, manganese, nickel, titanium, vanadium, antimony, cobalt, lead, cadmium, chromium, etc. Bismuth vanadates are non-cadmium yellows. These pigments may be milled to create nanoparticles which may be useful where transparency and low scattering is desired. Some of the light absorbing or light reflecting particles are electrically conductive. Electrically conductive particles can be used in combination with less conductive or non-conductive particles.

Some of major classes of dyes or pigments for the absorptive structure 30 include phthalocyanines, cyanine, transitional metal dithioline, squarylium, croconium, quinones, anthraquinones, iminium, pyrylium, thiapyrilium, azulenium, azo, perylene, and indoanilines. Many of these dyes and pigments can exhibit visible light absorption, infrared light absorption, or both. Further, many different types of visible dyes and colorants may be used, such as acid dyes, azoic coloring matters, coupling components, diazo components. Basic dyes include developers, direct dyes, disperse dyes, fluorescent brighteners, food dyes, ingrain dyes, leather dyes, mordant dyes, natural dyes and pigments, oxidation bases, pigments, reactive dyes, reducing agents, solvent dyes, sulfur dyes, condense sulfur dyes, or vat dyes. Some of the organic pigments may belong to one or more of monoazo, azo condensation insoluble metal salts of acid dyes and disazo, naphthols, arylides, diarylides, pyrazolone, acetoarylides, naphthanilides, phthalocyanines, anthraquinone, perylene, flavanthrone, triphenodioxazine, metal complexes, quinacridone, polypryrrolopyrrole, etc.

In some embodiments, the absorptive regions 32 of the absorptive structures 30 include a dried aqueous dispersion of an organic polymer. In general, a dried aqueous dispersion may be obtained by starting with a dispersion of material in a solvent (e.g., water) and drying the solvent to obtain the dried aqueous dispersion. Aqueous dispersions of organic polymers may include multiple ionic groups capable of electrostatic interaction. In some embodiments, these polymers also contain polymerized units that bear an ionic or ionizable group. However, the concentration of such groups is significantly lower such that the organic polymers can be dispersed in an aqueous solution, yet do not dissolve forming a solution. Thus, such organic polymers can be characterized as water insoluble. In other embodiments, organic polymers may be rendered water dispersible by use of ionic surfactants.

Water-soluble polyelectrolytes are typically insoluble in organic solvents, such as tetrahydrofuran (THF). In contrast, organic polymers (e.g., polyurethane and acrylic polymer) of aqueous dispersions are often soluble in organic solvents such as THF. By soluble it is meant that at least 50% of the coating (or at least 50% of the organic polymer portion of the coating when the coating has greater than 50 wt. % of light absorbing or light reflecting particles) is removed from the coated substrate (e.g., glass) after soaking in ajar containing organic solvent (e.g., THF) after 30 minutes in a bath sonicator (e.g., Branson Model 3510).

Non-limiting examples of organic polymer dispersions include polyurethane polymer dispersions, acrylic polymer dispersions, polyester dispersions, polyolefin dispersion, polyethylene and polypropylene dispersions and their copolymer dispersions including ethylene-vinyl acetate copolymer dispersions, epoxy dispersions, phenolic dispersions, polyimide and polyamide dispersions, vinyl chloride dispersions, and mixtures thereof. Such polymers are typically thermoplastic.

Any suitable refracting or diffracting layer 52 may be used, which may provide a beneficial optical functionality, such as improving angular color uniformity or brightness enhancement. Non-limiting types of refracting or diffracting layers 52 include structural diffracting or refracting layers, multilayer optical films, and color improvement layers.

Structural diffracting or refracting layers may include structures formed in the surface of the layer or embedded at an interface between two materials having different refractive indices within the layer, which may provide an optical functionality. Non-limiting examples of structural diffracting or refracting layers include microlens arrays, prismatic structures, lenticular arrays, microstructure Fresnel lenses, microstructured surface diffusers, holographic diffusers, volume phase gratings, nanostructures, diffractive optical elements, or metasurface optical elements.

Multilayer optical films may include any film having a plurality of alternating layers, which may provide an optical functionality, such as brightness enhancement. A multilayer optical film typically includes individual microlayers having different refractive index characteristics so that some light is reflected at interfaces between adjacent microlayers. The microlayers are sufficiently thin so that light reflected at a plurality of the interfaces undergoes constructive or destructive interference to give the multilayer optical film the desired reflective or transmissive properties. For multilayer optical films designed to reflect light at ultraviolet, visible, or near-infrared wavelengths, each microlayer generally has an optical thickness (a physical thickness multiplied by refractive index) of less than about 1 micrometer. However, thicker layers can also be included, such as skin layers at the outer surfaces of the multilayer optical film, or protective boundary layers (PBLs) disposed between the multilayer optical films, that separate the coherent groupings of microlayers. Such a multilayer optical film structure can also include one or more thick adhesive layers to bond two or more sheets of multilayer optical film in a laminate. Non-limiting examples of multilayer optical films include brightness enhancing films (BEFs).

Color improvement layers may include angular color improvement adhesive layers or other color correction components. In some embodiments, the color improvement layer includes a polymeric matrix and particles dispersed in the polymeric matrix, which may provide a low localized scattering anomalies (known as “sparkle”).

The color improvement layer may also include, or be described as, a bulk diffuser.

Examples of suitable color improvement layers may be found in, for example, International Publication No. WO 2018/204675 A1 (Hao et al.), which is incorporated herein by reference.

The particles in a color improvement layer have a particle size range of 400 nanometers (nm) to 3000 nm, or a particle size range of 700 nm to 2.0 micrometers (or microns). In some embodiments, the particle size range may be from 1 to 5 micrometers. In this context, “particle size” refers to the longest dimension of a particle, which is the diameter of a spherical particle. A “particle size range” refers to a distribution of particle sizes from the smallest to the largest (not an average). Thus, the particles are not necessarily uniform in size. The particle size can be determined by SEM.

The refracting or diffracting layer 52 may have any suitable thickness, or height, suitable for its particular function. The thickness may be greater than or equal to 10, 15, 25, 50, or even 75 micrometers. The thickness may be less than or equal to 100, 75, 50, 25, or even 15 micrometers. In some embodiments, the thickness of the refracting or diffracting layer 52 is in a range from 10 micrometers to 50 micrometers.

In some embodiments, the transmissive structure 26 may be formed of the same material and structure as the refracting or diffracting layer 52. For example, the transmissive structure 26 may be formed of the same material as a color improvement layer. In some embodiments, the transmissive structure 26 and the refracting or diffracting layer 52 may cooperatively provide a suitable thickness to perform an optical function and a thinner layer 52 may be used.

In other embodiments, the refracting or diffracting layer 52 may be omitted and the light control layer 12 may provide the optical functionality through the transmissive structure 26 having the material and structure of a refracting or diffracting layer 52. For example, a light control film may include only a circular polarizer 54 and a light control layer 12, which has material and structure otherwise found in a refracting or diffracting layer 52. In such embodiments, the light control layer 12 may be described as having an integrated refracting or diffracting layer 52.

FIG. 5 shows an enlarged first cross-sectional view of a light control layer 70 similar to the first cross-sectional view 34 (FIGS. 1 to 2C). The light control layer 70 may be used to replace the light control layer 12 in the display 10 (FIG. 1) or the display 50 (FIG. 3). Many of the components of the light control layer 70 are the same or similar to the components of the light control layer 12 except that the light control layer 70 includes absorptive regions 84 that are angled and the transmissive regions 78 are tapered. The shape of the absorptive regions 84 generally follows the contours of the transmissive regions 78.

In general, light control layers, such as the light control layer 12 (FIG. 1), the light control layer 100 (FIG. 4), and the light control layer 70 (FIG. 5), may be designed by modifying various parameters, such as pitch between regions, aspect ratios, and the distance between the absorptive regions and the array of light sources. Parameters related to these are shown in FIG. 5.

A transmissive structure 72 of the light control layer 70 may include a transmissive material 74 (or base layer) or an index-matching material 76 (or backfill layer) defining transmissive regions 78. Different transmissive regions 78 may have a different composition and structure. In the illustrated embodiment, transmissive region 78a includes transmissive material 74 (as a protrusion in the base layer) and transmissive region 78b includes transmissive filler material 76 (as filler in the channels formed by the base layer). The transmissive material 74 and the transmissive filler material 76 may be the same material or different index-matched materials. The transmissive regions 78a and the transmissive regions 78b may alternate along the first direction 20. An absorptive structure 80 may include absorptive material defining absorptive regions 84.

Each transmissive region 78a may define a top surface 77 and one or more sidewalls 79. In the illustrated embodiment, both the top surface 77 and the sidewalls 79 each have a linear shape in the cross-sectional view. In other embodiments, the top surface 77, the one or more sidewalls 79, or both may have non-linear or curvilinear shape. For example, the transmissive region 78a may have a rounded edge where the top surface 77 and the sidewalls 79 meet.

Each transmissive region 78b may define a bottom surface 81 and one or more sidewalls 83. An absorptive region 84 may be disposed between adjacent sidewalls 79, 83. Each absorptive region 84 may extend at least partially along the adjacent sidewalls 79, 83. In some embodiments, the portions of the sidewalls 79, 83 in contact with the absorptive regions 84 may have a linear shape and the portions of the sidewalls 79, 83 extending above the absorptive regions 84 may have a rounded, curvilinear, or otherwise non-linear shape.

To characterize the various shapes that the transmissive regions 78 and the absorptive regions 80 may take, certain parameters may be defined to measure these structures. Such parameters may include a maximum height, an average maximum height, a median width, and an average median width.

Each transmissive region 78 may define a maximum height T_{H} along the third direction 24. As used herein, the term “maximum height” refers to the largest height value for a particular region, especially if the region is non-uniform.

The maximum height T_{H} for each transmissive region 78a, 78b may be measured along the third direction 24 between a base point 86 and a peak point 88. For example, T_{H} for a transmissive region 78a may extend from the base point 86 at the lowest point of an adjacent absorptive region 84 to the peak point 88 at the highest point on the upper surface of the transmissive material 74. Similarly, T_{H} for a transmissive region 78b may extend from the base point 86 at the lowest point of an adjacent absorptive region 84 to the peak point 88 at the highest point on the upper surface of adjacent transmissive material 74.

An average maximum height H1 may be defined for a plurality of transmissive regions 78a, 78b. As used herein, the term “average maximum height” refers to an average of maximum heights for a plurality of regions.

Each transmissive region 78a, 78b may define a median width T_{W} along the first direction 20. As used herein, the term “median width” refers to a median width value for a particular region, especially if the region is non-uniform, measured at 50% along the maximum height of the region. As can be seen in FIG. 5, the width of each transmissive region 78a, 78b varies along its height. T_{W} may be measured at T_{H}/2 for each transmissive region 78a, 78b.

An average median width W1 may be defined for a plurality of transmissive regions 78a, 78b. As used herein, the term “average median width” refers to an average of median widths for a plurality of regions.

Each absorptive region 84 may define a maximum height A_{H} along the third direction 24. A_{H} for each absorptive region 84 may be measured from a lowest point of the absorptive material to a highest point of the absorptive material for the particular absorptive region 84. An average maximum height H2 may also be defined for a plurality of absorptive regions 84.

Each absorptive region 84 may define a median width A_{W} along the first direction 20. As can be seen in FIG. 5, A_{W} may be measured at A_{H}/2 for each absorptive region 84. An average median width W2 may be defined for a plurality of absorptive regions 84.

The aspect ratio H2/W2 between the heights and widths of the absorptive regions 84 may be selected to facilitate balancing absorption at high incidence angles yet high transmission at angles closer to normal for a particular display. H2/W2 may be greater than or equal to 1:1, 5:1, 10:1, 15:1, 20:1, 50:1, 75:1, 100:1, or even 150:1. H2/W2 may be less than or equal to 200:1, 150:1, 100:1, 75:1, 50:1, 20:1, 15:1, 10:1, or even 5:1. In some embodiments, H2/W2 may be range from 20:1 to 100:1.

The aspect ratio H2/W1 between the heights of the absorptive regions 84 and the widths of the transmissive regions 78 may be selected to facilitate balancing absorption at high incidence angles yet high transmission at angles closer to normal for a particular display. H2/W1 may be greater than or equal to 1:1, 2:1, 3:1, 4:1, 5:1, 10:1, 25:1, 50:1, 100:1, or even 150:1. H2/W1 may be less than or equal to 200:1, 150:1, 100:1, 50:1, 25:1, 10:1, 5:1, 4:1, 3:1, 2:1, or even 1:1. In some embodiments, H2/W1 may be in a range from 1:1 to 200:1.

An average pitch P2 may also be used to describe the plurality of absorptive regions 84. An aspect ratio P2/H2 between the average pitches and heights of the absorptive regions 84 may be selected to facilitate balancing absorption at high incidence angles yet high transmission at angles closer to normal for a particular display. P2/H2 may be greater than or equal to 1:2, 1:1, 2:1, 3:1, 4:1, 5:1, 10:1, 25:1, 50:1, or even 75:1. P2/H2 may be less than or equal to 100:1, 75:1, 50:1, 25:1, 10:1, 5:1, 4:1, 3:1, 2:1, or even 1:1. In some embodiments, P2/H2 may be in a range from 1:2 to 100:1.

A height ratio H2/H1 between the heights of the absorptive regions 84 and the heights of the transmissive regions 78 may be defined. The difference in height may be a result of the manufacturing process of the light control layer 70 (e.g., by etching). H2/H1 may be greater than or equal to 40%, 50%, 60%, 70%, 80%, or even 90%. H2/H1 may be less than or equal to 100%, 90%, 80%, 70%, 60%, or even 50%. In some embodiments, H2/H1 may be in a range from 50% to 100%.

A value for H2 may be selected for a particular application and may absorb less high angle incident light than a traditional privacy filter. H2 may be greater than or equal to 0.02, 0.05, 0.1, 0.5, 1, 5, 10, 25, 50, 100, or even 150 micrometers. H2 may be less than or equal to 200, 150, 100, 50, 25, 10, 5, 1, 0.5, 0.1, or even 0.05 micrometers. H2 may be in a range from 0.02 to 200 micrometers.

A value for W2 may be selected to facilitate high transmission normal to the axis. W2 may be less than or equal to 5, 4, 3, 2, 1.5, 1, 0.5, 0.25, or even 0.1 micrometer. In some embodiments, W2 may be in a range from 0.5 to 1 micrometer.

### Examples

As shown in Table 1, parameters for a light control layer were inputted into an optical model and various outputs were captured. The light control layers consisted of a square grid of absorbing louvers with a given pitch. The louvers were further defined by height and width. A louver aspect ratio was defined as the ratio of the louver height to the louver width.

Each light control layer was modeled in two configurations. The first configuration was used to determine the amount of diffuse reflection. The second configuration was used to determine standalone transmission properties of the light control layer such as axial transmission, total transmission, and full-width-at-half-maximum (FWHM) of transmitted light.

TABLE 1

| | | | | | | Axial | Total | |
|---|---|---|---|---|---|---|---|---|
| | | | | | Diffuse | Transmission | Transmission | |
| | Pitch | Height | Width | Aspect | Reflection | (% of | (% of | FWHM |
| Examples | (um) | (um) | (um) | (height/width) | (% of control) | control) | control) | (deg.) |
| C1 | 30 | 85 | 0.25 | 340 | 18 | 93 | 8 | 29 |
| C2 | 39 | 90 | 7.5 | 12 | 7 | 55 | 5 | 27 |
| 1 | 20 | 50 | 0.25 | 200 | 21 | 94 | 10 | 30 |
| 2 | 25 | 40 | 0.25 | 160 | 34 | 96 | 22 | 47 |
| 3 | 20 | 25 | 0.25 | 100 | 42 | 98 | 33 | 60 |
| 4 | 50 | 45 | 0.25 | 180 | 55 | 99 | 49 | 79 |
| 5 | 50 | 40 | 0.25 | 160 | 58 | 99 | 54 | 92 |
| 6 | 35 | 15 | 0.25 | 60 | 72 | 100 | 72 | 147 |
| 7 | 15 | 4 | 0.25 | 16 | 76 | 101 | 81 | 159 |
| 8 | 50 | 4 | 0.25 | 16 | 92 | 102 | 94 | 164 |

The first configuration had the following layer stack configuration: 100-nm-thick layer of A1, 10-μm-thick layer of optically clear adhesive (OCA), a 25-μm-thick layer of a volume diffuser, the light control layer, a 10-μm-thick layer of OCA, and a circular polarizer. The light control layer was modeled as louvers at the specified geometry with clear regions with a refractive index (n) of 1.49 and an extinction coefficient (k) of 0. The absorptive regions had an n of 1.49 with a k of 1. The volume diffusing layer consisted of nominally 2-μm particles at a specified concentration and refractive index difference to achieve approximately 80% scattering efficiency. The layer structure was illuminated with collimated, 532-nm light normally incident upon the circular polarizer. The intensity of the reflected light was captured on a conoscopic grid. The diffuse reflection was defined as the intensity of reflected light with a polar angle of greater than 5 degrees. A control configuration was modeled without a light control layer present. The change of diffuse reflection upon addition of a specified light control layer was shown in the table above.

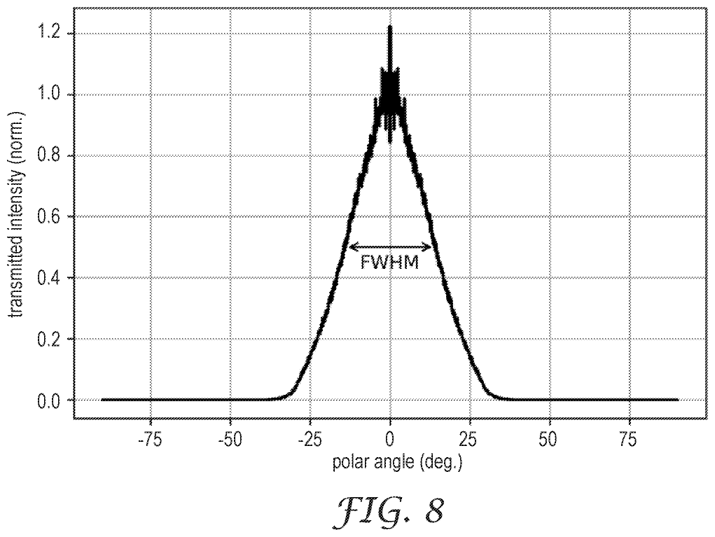

The second configuration had the following stack configuration: a 10-μm-thick layer of OCA, the light control layer, and a 10-μm-thick layer of OCA. The layer structure was illuminated with Lambertian, 532-nm light incident upon the bottom side of the layer stack. The intensity of transmitted light was recorded on a conoscopic grid. The total transmission was defined as the intensity of light that can transmit the layer stack. The axial transmission was defined as the intensity of light that can transmit the layer stack with a polar angle less than 2 degrees. The FWHM was defined as the angular width of the angular transmission profile where the intensity drops to 50% of the peak value. The FWHM of an example angular transmission profile is shown in FIG. 8. A control configuration was modeled without a light control layer present. The change in axial and total transmission upon addition of a specified light control layer is shown in Table 1.

In comparative example C1, the light control layer is with a sufficiently high aspect ratio to yield a small narrow FWHM yet maintain a high degree of axial transmission. However, given the absolute dimensions for the louver pitch and height, the total transmission of the light control layer remains less than 10% of the control.

In comparative example C2, the aspect ratio of the louvers in the light control layer is reduced compared to C1. To achieve the same FWHM as C1 the louver width is increased resulting in a reduced amount of axial transmission compared to C1 with a similarly low total transmission.

In examples 1-8, light control layers are specified to achieve useful ranges of diffuse reflection while maintaining high axial transmission.

Thus, various embodiments of a LIGHT CONTROL LAYER FOR AMBIENT CONTRAST CONTROL are disclosed. Although reference is made herein to the accompanying set of drawings that form part of this disclosure, one of at least ordinary skill in the art will appreciate that various adaptations and modifications of the embodiments described herein are within, or do not depart from, the scope of this disclosure. For example, aspects of the embodiments described herein may be combined in a variety of ways with each other. Therefore, it is to be understood that, within the scope of the appended claims, the claimed invention may be practiced other than as explicitly described herein.

Terms related to orientation, such as “highest,” “lowest,” “above,” or “below,” are used to describe relative positions of components and are not meant to limit the absolute orientation of the embodiments contemplated.

1. A light control film comprising:
a light control layer comprising:
a first major surface and a second major surface opposite the first major surface, each surface extending in at least a first direction and a second direction, the surfaces being separated along a third direction orthogonal to the first and second directions;
at least one transmissive structure defining transmissive regions disposed between the first major surface and the second major surface; and
at least one absorptive structure defining absorptive regions disposed between the first major surface and the second major surface,
wherein a first cross-section of the film extending along the first and third directions has alternating transmissive and absorptive regions along the first direction,
wherein a second cross-section of the film extending along the second and third directions has at least one transmissive region or absorptive region along the second direction,
wherein the transmissive regions have an average maximum height H1 defined along the third direction and average median width W1 defined along the first direction,
wherein the absorptive regions have an average maximum height H2 defined along the third direction and average median width W2 defined along the first direction,
wherein H2/W1 is greater than or equal to 1:1, and
wherein H2/W2 is greater than or equal to 20:1.

2. The light control film of claim 1, wherein the second cross-section of the film extending along the second and third directions has alternating transmissive and absorptive regions along the second direction.

3. The light control film of claim 1, wherein a third cross-section of the film extending along the first and second directions has the at least one absorptive structure defining a two-dimensional shape.

4. The light control film of claim 1, wherein H2 is less than or equal to 2 micrometers.

5. The light control film of claim 1, wherein H2/W2 is less than or equal to 100:1.

6. The light control film of claim 1, wherein the absorptive regions comprise light-absorbing or light-reflecting particles.

7. The light control film of claim 1, further comprising a structural diffracting or refracting layer disposed on the light control layer.

8. The light control film of claim 1, further comprising a multilayer optical film layer disposed on the light control layer.

9. The light control film of claim 1, wherein further comprising a color improvement layer having a polymeric matrix and particles dispersed in the polymeric matrix.

10. The light control film of claim 1, further comprising a circular polarizer disposed on the light control layer.

11. The light control film of claim 1, wherein H2/H1 is at least 50%.

12. The light control film of claim 1, further comprising an array of light sources.

13. The light control film of claim 12, further comprising a light-emitting layer, wherein the array of light sources is at least partially disposed in the light-emitting layer, wherein the light control layer is disposed on the light-emitting layer.

14. The light control film of claim 12, wherein the array of light sources is at least partially disposed in the light control layer.

15. The light control film of claim 12, wherein the array of light sources defines an average pitch P3 in the first direction, wherein the absorptive regions of the at least one absorptive structure defines an average pitch P2 equal to the first average pitch along the first direction.

16. A display comprising the light control film of claim 1.

17. An optical film configured to be disposed on, and improve an ambient contrast ratio of, a display, the optical film comprising a plurality of alternating visible light transmissive and visible light absorbing regions disposed and extending between opposing major first and second surfaces, the light absorbing regions having an average median width W2 and an average maximum height H2 such that H2/W2≥10:1 and, for substantially Lambertian incident light in a visible wavelength range from about 380 nm to about 780 nm, an optical transmittance of the optical film versus an incident angle of the incident light has a full width at half maximum (FWHM) of greater than or equal to about 80 degrees.

18. An optical film configured to be disposed on, and improve an ambient contrast ratio of, a display, the optical film comprising a plurality of alternating visible light transmissive and visible light absorbing regions disposed and extending between opposing major first and second surfaces, the light absorbing regions having an average median width W2 and an average maximum height H2 such that H2/W2≥10:1 and an average pitch distance P2 between adjacent visible light absorbing regions such that P2/H2>1.
